(19) United States
(12) Patent Application Publication
(10) Pub. No.: US 2025/0063915 A1
(43) Pub. Date: Feb. 20, 2025

(54) DISPLAY PANEL AND DISPLAY TERMINAL

(71) Applicant: Shenzhen China Star Optoelectronics Semiconductor Display Technology Co., Ltd., Shenzhen (CN)

(72) Inventor: Zhiyuan YIN, Shenzhen (CN)

(73) Assignee: Shenzhen China Star Optoelectronics Semiconductor Display Technology Co., Ltd., Shenzhen (CN)

(21) Appl. No.: 18/399,377

(22) Filed: Dec. 28, 2023

(30) Foreign Application Priority Data
Aug. 18, 2023 (CN) 202311047439.5

(51) Int. Cl. H10K 59/35; H10K 50/19

(52) U.S. Cl. CPC H10K 59/353; H10K 50/19

(57) ABSTRACT

Disclosed are a display panel and a display terminal. The display panel includes a plurality of first sub-pixels, a plurality of second sub-pixels, and a plurality of third sub-pixels, two adjacent first sub-pixels form one group, two adjacent second sub-pixels form one group, two adjacent third sub-pixels form one group, a minimum distance between centers of first sub-pixels of a plurality of groups is a first distance, a minimum distance between centers of second sub-pixels of a plurality of groups is a second distance, a minimum distance between centers of third sub-pixels of a plurality of groups is a third distance, the first distance is greater than the second distance, and the first distance is greater than the third distance.

### CROSS-REFERENCE TO RELATED APPLICATION

This application claims priority to Chinese Patent Application No. 202311047439.5, filed in the China National Intellectual Property Administration on Aug. 18, 2023, entitled “DISPLAY PANEL AND DISPLAY TERMINAL”, the entire contents of which are incorporated herein by reference.

### TECHNICAL FIELD

The present disclosure relates to a field of display technologies, and more particularly, to a display panel and a display terminal.

### BACKGROUND

An OLED (Organic Light-Emitting Diode) display technology is a new display technology. In an OLED display panel, the metal electrodes of pixels are arranged in an array. In a screen-off state, the metal electrode may reflect light, and interference between the reflected light is formed, thereby causing a significant color separation problem macroscopically.

Therefore, how to solve a problem of color separation of a display panel is one of the technical problems urgently needed to be solved by a person skilled in the art.

### SUMMARY

The present disclosure provides a display panel and a display terminal that may improve the color separation of display panels.

To solve the above technical problem, the present disclosure provides the following technical solutions.

The present disclosure provides a display panel including a plurality of first sub-pixels, a plurality of second sub-pixels, and a plurality of third sub-pixels having different colors of emitted light. Two adjacent first sub-pixels form one group, two adjacent second sub-pixels form one group, two adjacent third sub-pixels form one group, a minimum distance between centers of first sub-pixels of a plurality of groups is a first distance, a minimum distance between centers of second sub-pixels of a plurality of groups is a second distance, a minimum distance between centers of third sub-pixels of a plurality of groups is a third distance, the first distance is greater than the second distance, and the first distance is greater than the third distance.

The present disclosure further provides a display terminal including the display panel described above.

### DESCRIPTION OF DRAWINGS

The technical solution and other beneficial effects of the present disclosure will be apparent from the following detailed description of specific embodiments thereof, taken in conjunction with the accompanying drawings.

FIG. 1 is a schematic diagram of a pixel structure of a display panel according to the present disclosure;

FIG. 2 is a schematic cross-sectional view of a display panel according to the present disclosure;

FIG. 3 is a schematic cross-sectional view of another display panel according to the present disclosure; and

FIG. 4 is a schematic top view of a display panel according to the present disclosure.

List of reference signs: First sub-pixel 10, Second sub-pixel 20, Third sub-pixel 30, First direction Y, Second direction X, Repeating unit 100, First sub-repeating unit 103, Second sub-repeating unit 104, First dummy triangle 101, Second dummy triangle 102, Light-emitting material layer 110, Third light-emitting material layer 113, First sub-layer 1131, Second sub-layer 1132, Second light-emitting material layer 112, First light-emitting material layer 111, Array substrate 40, Anode 131, Cathode 135, First display portion 16, Second display portion 17, Display area AA, Non-display area NA, Flat layer 136, Pixel definition layer 137, Hole injection layer 132, Hole transport layer 133, Electron transport layer 134, Encapsulation layer 140, Cover plate 150, Auxiliary function layer 124, First electron transport layer 121, Charge generation layer 122, and First hole transport layer 123.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure. In addition, it should be understood that the specific implementations described here are only used to illustrate and explain the present disclosure, and are not used to limit the present disclosure. In the present disclosure, unless otherwise stated, directional words used such as “upper” and “lower” generally refer to the upper and lower directions of the device in actual use or working state, and specifically refer to the drawing directions in the drawings; and “inner” and “outer” refer to the outline of the device.

The present disclosure provides the following solution based on the above-mentioned technical problem.

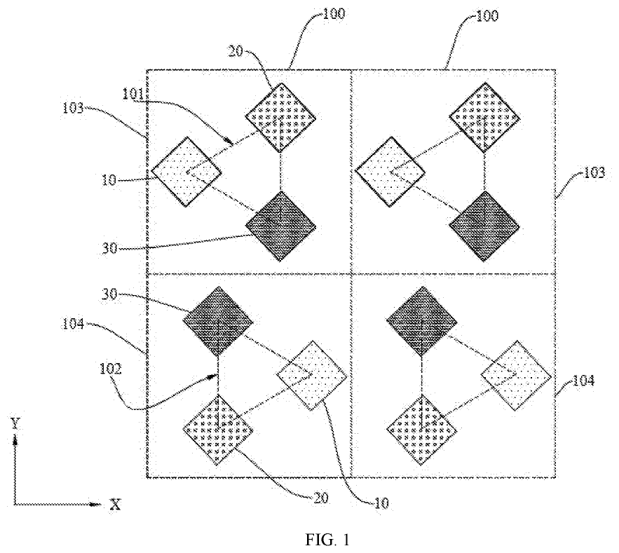

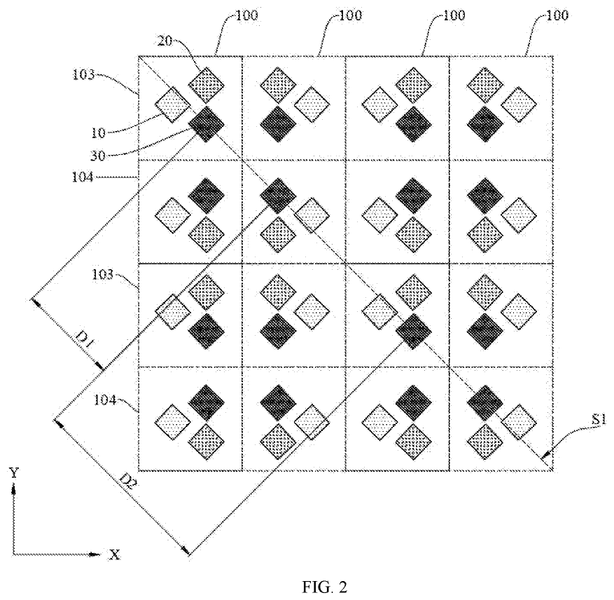

Referring to FIGS. 1 and 2, the present disclosure provides a display panel including a plurality of first sub-pixels 10, a plurality of second sub-pixels 20, and a plurality of third sub-pixels 30 having different light emitting colors; two adjacent first sub-pixels 10 form one group, two adjacent second sub-pixels 20 form one group, two adjacent third sub-pixels 30 form one group, a minimum distance between centers of first sub-pixels 10 of a plurality of groups is a first distance, a minimum distance between centers of second sub-pixels 20 of a plurality of groups is a second distance, a minimum distance between centers of third sub-pixels 30 of a plurality of groups is a third distance, the first distance is greater than the second distance, and the first distance is greater than the third distance.

In the present disclosure, the minimum distance between the centers of the two adjacent first sub-pixels 10 of the display panel is set to be greater than the minimum distances between the centers of the two adjacent same-color pixels of the other two types of pixels, thereby increasing the distance between the centers of the two adjacent first sub-pixels 10, weakening the interference between the two adjacent first sub-pixels 10, and improving the color separation problem due to interference of light.

Referring to FIGS. 1 and 2, which are schematic diagrams of two arrangements of a plurality of sub-pixels of a display panel, there are a plurality of different distances between centers of any two adjacent first sub-pixels 10, and the smallest distance of the plurality of different distances is the first distance. There are a plurality of different distances between centers of any two adjacent second sub-pixels 20, and the smallest distance of the plurality of different distances is the second distance. There are a plurality of different distances between centers of any two adjacent third sub-pixels 30, and the smallest distance of the plurality of different distances is the third distance. For ease of description, in the present disclosure, any two adjacent first sub-pixels 10 are referred to as one group, any two adjacent second sub-pixels 20 are referred to as one group, and any two adjacent third sub-pixels 30 are referred to as one group. The distance between the centers of the first sub-pixels 10 of the plurality of groups refers to the distance between the centers of the first sub-pixels 10 in any one of the plurality of groups, and the smallest distance is the first distance. Similarly, the distance between the centers of the second sub-pixels 20 of the plurality of groups refers to the distance between the centers of the second sub-pixels 20 in any one of the plurality of groups, and the smallest distance is the second distance. The distance between the centers of the third sub-pixels 30 of the plurality of groups refers to the distance between the centers of the third sub-pixels 30 in any one of the plurality of groups, and the smallest distance is the third distance.

By setting the first distance to be greater than the second distance and the third distance, the interference between the two adjacent first sub-pixels 10 is reduced, and the problem of color separation is improved.

In the present embodiment, the colors of the first sub-pixel 10, the second sub-pixel 20, and the third sub-pixel 30 are different. For example, each of the first sub-pixel 10, the second sub-pixel 20, and the third sub-pixel 30 may be one of red sub-pixels, green sub-pixels, and blue sub-pixels.

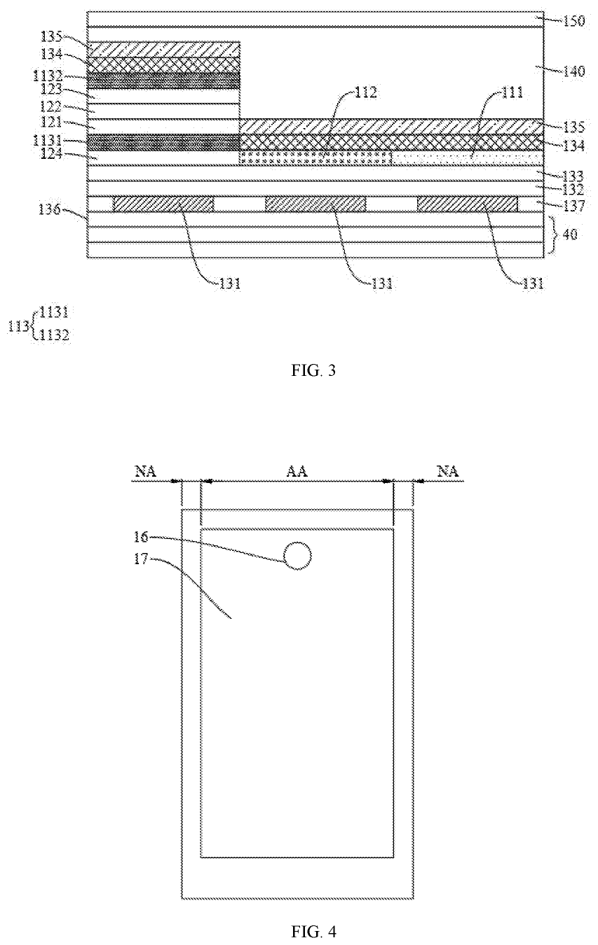

As shown in FIG. 3, the display panel includes an array substrate 40 and an anode 131 disposed on the array substrate 40, and the array substrate 40 includes a plurality of thin film transistors (not shown) arranged in an array. A source and drain layer of the thin film transistor is electrically connected to the anode 131 to provide a driving signal for the anode 131. The array substrate 40 may include a flat layer 136 located at a side of the anode 131 away from a light emitting surface of the display panel. The display panel also includes a pixel definition layer 137 including a plurality of openings, and the sub-pixels correspond to the openings one-to-one.

The display panel further includes a hole injection layer 132, a hole transport layer 133, a light-emitting material layer 110, an electron transport layer 134, and a cathode 135 laminated on the anode 131. The anode 131 serves to provide holes, the hole transport layer 133 serves to transport holes to the light-emitting material layer 110, the cathode 135 serves to provide electrons, and the electron transport layer 134 serves to transport electrons to the light-emitting material layer 110, the holes and electrons are recombined in the light-emitting material layer 110 to emit light. One pixel corresponds to one anode 131. The cathode 135 of the display panel may be arranged continuously to provide a voltage signal for all pixels.

The light-emitting material layer 110 of the display panel may be formed using an evaporation process or an inkjet printing process. When the inkjet printing process is used, the usage count of the photomask can be reduced, and the material cost of the light-emitting material layer 110 can also be reduced.

The display panel may also include an encapsulation layer 140 disposed on the cathode 135, and the encapsulation layer 140 may be a thin film encapsulation. For example, the encapsulation layer 140 may include, but is not limited to, a multilayer structure of an inorganic layer, an organic layer, and an inorganic layer which are stacked on top of each other. The organic layer of the encapsulation layer 140 has the effect of flattening, and can form a flat upper surface. For example, when the number of layers of the light-emitting material layer 110 of sub-pixels of different colors is different, the organic layer can improve the discontinuity due to the unevenness, so that the surface of the organic layer away from the array substrate 40 is smooth, thereby not affecting the surface flatness of the display panel.

The display panel may further include a cover plate 150 disposed on the encapsulation layer 140, which may be, but is not limited to, UFG (Ultra Foldable Glass), Ultra-thin glass (UTG), colorless polyimide, or the like. The cover plate 150 has a certain anti-impact capability, and can protect the display panel from damage caused by an external force.

The technical solution of the present disclosure will now be described in connection with specific examples.

As shown in FIG. 1, in the present embodiment, at least two groups have different distances between two adjacent first sub-pixels 10. FIG. 1 shows four adjacent first sub-pixels 10 divided into two rows and two columns. Two pixels of a first row are taken as the first group, and the distance between the centers of the first sub-pixels 10 of the first group is L1. Two first sub-pixels 10 of a first column are taken as the second group, and the distance between the centers of the first sub-pixels 10 of the second group is L2. L1 and L2 are not equal. With the above arrangement, the distances of the adjacent plurality of first sub-pixels 10 can be differentiated, thereby reducing the interference between the two adjacent first sub-pixels 10 in a plurality of directions and reducing the problem of color separation.

Similarly, at least two groups have different distances between two adjacent second sub-pixels 20; and/or, at least two groups have different distances between two adjacent third sub-pixels 30. That is, for at least one of the first sub-pixel 10, the second sub-pixel 20, and the third sub-pixel 30, two groups have different distances between two adjacent sub-pixels, so that the effect of reducing color separation may be realized.

By setting the distances between the plurality of adjacent first sub-pixels 10, the distances between the plurality of adjacent second sub-pixels 20, and the distances between the plurality of adjacent third sub-pixels 30 to be different, the light interference between the plurality of sub-pixels may be further reduced, and the color separation problem may be reduced. That is, when more groups of two adjacent sub-pixels have different distances, the effect of reducing color separation is better.

As shown in FIG. 1, in the present embodiment, the display panel includes a plurality of repeating units 100 arranged in a first direction Y and a second direction X, the second direction X is perpendicular to the first direction Y, the repeating unit 100 includes a first sub-repeating unit 103 and a second sub-repeating unit 104, the first sub-repeating unit 103 includes a first sub-pixel 10, a second sub-pixel 20 and a third sub-pixel 30, the centers of the first sub-pixel 10, the second sub-pixel 20 and the third sub-pixel 30 are connected with each other to form a first dummy triangle 101; the second sub-repeating unit 104 includes a first sub-pixel 10, a second sub-pixel 20, and a third sub-pixel 30, and the centers of the first sub-pixel 10, the second sub-pixel 20, and the third sub-pixel 30 are connected with each other to form a second dummy triangle 102; and the first dummy triangle and the second dummy triangle may be arranged in the first direction Y, but are not limited thereto. The first dummy triangle 101 is centrally symmetrical with the second dummy triangle 102, and in the first sub-repeating unit 103 or the second sub-repeating unit 104, a line connecting the center of the second sub-pixel 20 and the center of the third sub-pixel 30 is parallel to the first direction Y.

In the first sub-repeating unit 103, the centers of the first sub-pixel 10, the second sub-pixel 20, and the third sub-pixel 30 constitute the vertices of the first dummy triangle 101, and in the second sub-repeating unit 104, the centers of the first sub-pixel 10, the second sub-pixel 20, and the third sub-pixel 30 constitute the vertices of the second dummy triangle 102.

Two repeating units 100 arranged in the second direction X are shown in FIG. 1. In the same repeating unit 100, the first dummy triangle 101 is centrally symmetrical with the second dummy triangle 102, that is, in the same repeating unit 100, the first dummy triangle 101 may overlap the second dummy triangle 102 after 180 degrees of rotation. In any dummy triangle, the line connecting the center of the second sub-pixel 20 and the center of the third sub-pixel 30 is parallel to the first direction Y. By arranging the first sub-pixel 10, the second sub-pixel 20, and the third sub-pixel 30 in the above-described manner, it is possible to form a triangular arrangement such that the first distance is greater than the second distance, and the first distance is greater than the third distance. Meanwhile, the triangular arrangement supports SPR (Sub Pixel Rendering) to achieve a display effect of high PPI (Pixel Per Inch).

In the present embodiment, the first sub-pixel 10, the second sub-pixel 20, and the third sub-pixel 30 may be circular, polygonal, or the like. When the first sub-pixel 10, the second sub-pixel 20, and the third sub-pixel 30 are polygons, the polygon may be a regular polygon or an irregular polygon. For example, the polygon may be a square, a regular pentagon, a regular hexagon, or the like. It is not limited in this disclosure. When the polygon is the regular polygon, the sub-pixels have symmetry, and the display effect is better.

As shown in FIG. 2, in the present embodiment, the third sub-pixel 30 is a polygon, and the centers of the plurality of third sub-pixels 30 are collinear in a direction of at least a first straight line S1.

It should be noted that the direction of the first straight line S1 can be adjusted adaptively according to the shape of the sub-pixel.

For example, when the shape of the sub-pixel is square, the direction of the first straight line S1 may be a perpendicular line direction of a side of the square. When the shape of the sub-pixel is circular, the first straight line S1 may be in any direction through the center of the circle. When the shape of the sub-pixel is a polygon, the first straight line S1 may be a perpendicular line direction of a side of the polygon.

Alternatively, the first straight line S1 may be a perpendicular line of the shortest side of the polygon. Since the diffraction is strongest in the perpendicular line direction of the shortest side of the polygon, when the first straight line S1 is set as the perpendicular line of the shortest side of the polygon, the diffraction effect can be better reduced and the color separation problem can be improved. Alternatively, the first straight line S1 may be the perpendicular bisector of the shortest side of the polygon, and the centers of the plurality of third sub-pixels 30 are located on the first straight line S1, so that the symmetry of the arrangement of the sub-pixels can be improved and the display effect can be improved.

In the direction of the first straight line S1, the plurality of groups of the third sub-pixels 30 have different distances between the centers of the third sub-pixels 30. As shown in FIG. 2, in the direction of the first straight line S1, the distance between the centers of two adjacent third sub-pixels 30 of one group is D1, and the distance between the centers of two adjacent third sub-pixels 30 of the other group is D2, and D1 and D2 are different. The direction of the first straight line S1 may also be a direction coinciding with the other diagonal of the first sub-repeating unit 103. This disclosure is not limited.

By the above arrangement, the interference of the reflected light between the third sub-pixels 30 in the direction of the first straight line S1 can be reduced, thereby improving the color separation problem due to the interference of the light.

Further, as shown in FIG. 1, in the present embodiment, the second distance is greater than the third distance. By setting the second distance to be greater than the third distance, the first distance, the second distance, and the third distance can be made different, so that interference between subpixels of any one color can be reduced, and the color separation problem can be improved.

In the present embodiment, as shown in FIG. 2, the third sub-pixel 30 may be rectangular, and at least one side of the third sub-pixel 30 is included at an angle of 45 degrees with the first direction Y.

As shown in FIG. 3, FIG. 3 is a schematic sectional view of a display panel. In the present embodiment, the display panel includes an array-arranged light-emitting material layer 110, the third sub-pixel 30 includes at least two layers of the light-emitting material layers 110 stacked on top of each other, and the number of the light-emitting material layer 110 of the third sub-pixel 30 is greater than the number of the light-emitting material layer 110 of the first sub-pixel 10, and the number of the light-emitting material layer 110 of the third sub-pixel 30 is greater than the number of the light-emitting material layer 110 of the second sub-pixel 20.

In the present embodiment, the light-emitting material layer 110 of the second sub-pixel 20 includes a second light-emitting material layer 112. The second sub-pixel 20 includes the hole injection layer 132, the hole transport layer 133, the second light-emitting material layer 112, and the electron transport layer 134 stacked in sequence.

The light-emitting material layer 110 of the first sub-pixel 10 includes a first light-emitting material layer 111. The first sub-pixel 10 includes the hole injection layer 132, the hole transport layer 133, the first light-emitting material layer 111, and the electron transport layer 134 stacked in sequence.

The light-emitting material layer 110 of the third sub-pixel 30 includes a third light-emitting material layer 113 including a first sub-layer 1131 and a second sub-layer 1132. The first sub-layer 1131 and the second sub-layer 1132 are stacked in series, so that the light emission efficiency of the third sub-pixel 30 can be increased by the above arrangement. Specifically, a charge generation layer (CGL) 122 and a first hole transport layer 123 may be provided between the first sub-layer 1131 and the second sub-layer 1132, the charge generation layer 122 may be an N-type charge generation layer N-CGL or a P-type charge generation layer P-CGL, and the first hole transport layer 123 may be a P+HTL layer doped with a P-type material, but is not limited thereto.

In this embodiment, the third sub-pixel 30 may include the hole injection layer 132, the hole transport layer 133, the first sub-layer 1131, the first electron transport layer 121, the charge generation layer 122, the first hole transport layer 123, the second sub-layer 1132, and the electron transport layer 134 stacked in sequence. By the above arrangement, the series OLED (Tandem OLED) can be formed, the light emission efficiency of the third sub-pixel 30 can be increased, and the reflectivity of the third sub-pixel 30 can be reduced. By reducing the reflectivity of the third sub-pixel 30, the interference effect between the third sub-pixel 30 and the second sub-pixel 20 or the first sub-pixel 10 can be destroyed, and the diffraction effect of the third sub-pixel 30 can also be reduced, thereby further improving the color separation problem.

In some embodiments, the third sub-pixel 30 may also include an auxiliary function layer 124 disposed between the hole transport layer 133 and the first sub-layer 1131. The auxiliary function layer 124 may adjust the OLED device to achieve a better display effect. For example, the auxiliary function layer 124 may adjust the hole injection efficiency below, or block electrons of the first sub-layer 1131.

Further, in some embodiments, the third sub-pixel 30 is a blue sub-pixel. Since the luminous efficiency of the blue sub-pixel is less than that of the red sub-pixel and the green sub-pixel, the luminous efficiency of the blue sub-pixel can be increased by using a series design of the blue sub-pixel, so that the luminous efficiency of the three-color pixels of the display panel is relatively close. It is also possible to reduce the diffraction effect of the blue sub-pixel, and destroy the interference efficiency between the blue sub-pixel and the other red sub-pixel or the green sub-pixel in one white light pixel, by reducing the reflectivity of the blue sub-pixel.

Further, in some embodiments, the number of the light-emitting material layers 110 of the third sub-pixel 30 is two, the number of the light-emitting material layers 110 of the first sub-pixel 10 is one, and the number of the light-emitting material layers 110 of the second sub-pixel 20 is one.

Alternatively, the third sub-pixel 30 may be a blue sub-pixel, while the second distance is greater than the third distance. Although the distance between the centers of the two adjacent blue sub-pixels is smallest at this time, since the number of the light-emitting material layers 110 of the blue sub-pixels is greater than the number of the light-emitting material layers 110 of the pixels of the other two colors, the reflectivity of the anode 131 of the blue sub-pixels is the lowest. The final effect is that the interference between adjacent blue sub-pixels is weak. Accordingly, although the reflectivity of the anodes 131 of the red sub-pixel and the green sub-pixel is higher than that of the anodes 131 of the blue sub-pixel because the number of the light-emitting material layers 110 of the red sub-pixel and the green sub-pixel is less than the number of the light-emitting material layers 110 of the blue sub-pixel, interference is also weakened because the distance between adjacent red sub-pixels and the distance between adjacent green sub-pixels is greater. With the above arrangement, it is possible to match the number of light-emitting layers with the distance between adjacent pixels, thereby reducing interference in two ways.

As shown in FIG. 4, in the present embodiment, the display panel includes a first display portion 16 and a second display portion 17, and the light transmittance of the first display portion 16 is greater than the light transmittance of the second display portion 17. The first display portion 16 may correspond to a functional device of the display panel. For example, the functional device may be a camera or the like, but is not limited thereto.

As shown in FIG. 4, both the first display portion 16 and the second display portion 17 are located in the display area AA of the display panel, and both the first display portion 16 and the second display portion 17 can be used to display an image. The display panel further includes a non-display area NA located at the periphery of the display area AA.

The camera is disposed on the backlight side of the display panel, and the orthographic projection of the camera on the display panel is located on the first display portion 16. Since the light transmittance of the first display portion 16 is greater than the light transmittance of the second display portion 17, the problem of image quality degradation caused by light diffraction can be solved in addition to improving the color separation problem of the camera area. Compared with the display panel according to the related art, the diffraction effect of the first display portion 16 of the display panel according to the present disclosure is reduced, and the problem that the quality of the photographed image is degraded due to the diffraction effect is also improved.

Further, in all the above embodiments, the first sub-pixel 10 is a green sub-pixel, the second sub-pixel 20 is a red sub-pixel, and the third sub-pixel 30 is a blue sub-pixel. With the above arrangement, it is possible to increase the luminous efficiency of the blue sub-pixels so that the luminous efficiency of the sub-pixels of the three colors tends to be close. On the other hand, the third distance of the blue sub-pixels in the direction of the first straight line S1 may be minimized, thereby reducing the refractive index of the blue sub-pixels and reducing interference of the blue sub-pixels in the direction of the first straight line S1. Further, in the direction of the first straight line S1, the distances between adjacent blue sub-pixels are different, that is, D1 and D2 are different, so that the interference of the blue sub-pixels can be further reduced, thereby further improving the color separation problem.

The present disclosure further provides a display terminal including the display panel described above.

In the present embodiment, the display terminal may be any product or component having a display function such as a mobile phone, a tablet computer, a television, a display, a notebook computer, a digital photo frame, or a navigator.

In the above-mentioned embodiments, the description of each embodiment has its own emphasis, and parts not described in detail in a certain embodiment may be referred to the related description of other embodiments.

The display panel and the display terminal according to the embodiments of the present disclosure are described in detail above. The principles and embodiments of the present disclosure are described herein with reference to specific embodiments. The description of the above embodiments is merely intended to assist in understanding the technical solution of the present disclosure and the core concepts thereof. It may be appreciated by those ordinary skilled in the art that modifications may still be made to the technical solutions described in the foregoing embodiments, or equivalent replacements may be made to some of the technical features therein. These modifications or substitutions do not cause the essence of the corresponding technical solutions to deviate from the scope of the technical solutions of the embodiments of the present disclosure.

What is claimed is:

1. A display panel comprising a plurality of first sub-pixels, a plurality of second sub-pixels, and a plurality of third sub-pixels having different colors of emitted light;
wherein two adjacent first sub-pixels of the plurality of first sub-pixels form one group, two adjacent second sub-pixels of the plurality of second sub-pixels form one group, two adjacent third sub-pixels of the plurality of third sub-pixels form one group, a minimum distance between centers of first sub-pixels of a plurality of groups is a first distance, a minimum distance between centers of second sub-pixels of a plurality of groups is a second distance, a minimum distance between centers of third sub-pixels of a plurality of groups is a third distance, the first distance is greater than the second distance, and the first distance is greater than the third distance.

2. The display panel according to claim 1, wherein the display panel comprises a plurality of repeating units arranged in a first direction and a second direction, the second direction is perpendicular to the first direction, and each of the repeating units comprises:
a first sub-repeating unit comprising a first sub-pixel, a second sub-pixel, and a third sub-pixel, wherein lines connecting centers of the first sub-pixel, the second sub-pixel, and the third sub-pixel form a first dummy triangle; and
a second sub-repeating unit comprising a first sub-pixel, a second sub-pixel, and a third sub-pixel, wherein lines connecting centers of the first sub-pixel, the second sub-pixel, and the third sub-pixel form a second dummy triangle;
wherein the first dummy triangle is centrally symmetrical with the second dummy triangle, and in the first sub-repeating unit or the second sub-repeating unit, a line connecting the center of the second sub-pixel and the center of the third sub-pixel is parallel to the first direction.

3. The display panel according to claim 2, wherein the third sub-pixels are polygons, centers of a plurality of third sub-pixels in at least one direction are collinear, and distances between centers of third sub-pixels of a plurality of groups are different.

4. The display panel according to claim 3, wherein the third distance is less than the second distance.

5. The display panel according to claim 4, wherein an angle between at least one side of the third sub-pixel and the first direction is 45 degrees.

6. The display panel according to claim 1, wherein the display panel comprises a light-emitting material layer, the third sub-pixel comprises at least two light-emitting material layers stacked, and the number of the light-emitting material layer of the third sub-pixel is greater than the number of the light-emitting material layer of the first sub-pixel, and the number of the light-emitting material layer of the third sub-pixel is greater than the number of the light-emitting material layer of the second sub-pixel.

7. The display panel according to claim 6, wherein the number of the light-emitting material layer of the third sub-pixel is two, the number of the light-emitting material layer of the first sub-pixel is one, and the number of the light-emitting material layer of the second sub-pixel is one.

8. The display panel according to claim 1, wherein the display panel comprises a first display portion and a second display portion, and a light transmittance of the first display portion is greater than a light transmittance of the second display portion.

9. The display panel according to claim 1, wherein the first sub-pixel is a green sub-pixel, the second sub-pixel is a red sub-pixel, and the third sub-pixel is a blue sub-pixel.

10. A display terminal comprising a display panel, wherein the display panel comprises: a plurality of first sub-pixels, a plurality of second sub-pixels, and a plurality of third sub-pixels having different colors of emitted light;
wherein two adjacent first sub-pixels of the plurality of first sub-pixels form one group, two adjacent second sub-pixels of the plurality of second sub-pixels form one group, two adjacent third sub-pixels of the plurality of third sub-pixels form one group, a minimum distance between centers of first sub-pixels of a plurality of groups is a first distance, a minimum distance between centers of second sub-pixels of a plurality of groups is a second distance, a minimum distance between centers of third sub-pixels of a plurality of groups is a third distance, the first distance is greater than the second distance, and the first distance is greater than the third distance.

11. The display terminal according to claim 10, wherein the display panel comprises a plurality of repeating units arranged in a first direction and a second direction, the second direction is perpendicular to the first direction, and each of the repeating units comprises:
a first sub-repeating unit comprising a first sub-pixel, a second sub-pixel, and a third sub-pixel, wherein lines connecting centers of the first sub-pixel, the second sub-pixel, and the third sub-pixel form a first dummy triangle; and
a second sub-repeating unit comprising a first sub-pixel, a second sub-pixel, and a third sub-pixel, wherein lines connecting centers of the first sub-pixel, the second sub-pixel, and the third sub-pixel form a second dummy triangle;
wherein the first dummy triangle is centrally symmetrical with the second dummy triangle, and in the first sub-repeating unit or the second sub-repeating unit, a line connecting the center of the second sub-pixel and the center of the third sub-pixel is parallel to the first direction.

12. The display terminal according to claim 11, wherein the third sub-pixels are polygons, centers of a plurality of third sub-pixels in at least one direction are collinear, and distances between centers of third sub-pixels of a plurality of groups are different.

13. The display terminal according to claim 12, wherein the third distance is less than the second distance.

14. The display terminal according to claim 13, wherein an angle between at least one side of the third sub-pixel and the first direction is 45 degrees.

15. The display terminal according to claim 10, wherein the display panel comprises a light-emitting material layer, the third sub-pixel comprises at least two light-emitting material layers stacked, and the number of the light-emitting material layer of the third sub-pixel is greater than the number of the light-emitting material layer of the first sub-pixel, and the number of the light-emitting material layer of the third sub-pixel is greater than the number of the light-emitting material layer of the second sub-pixel.

16. The display terminal according to claim 15, wherein the number of the light-emitting material layer of the third sub-pixel is two, the number of the light-emitting material layer of the first sub-pixel is one, and the number of the light-emitting material layer of the second sub-pixel is one.

17. The display terminal according to claim 10, wherein the display panel comprises a first display portion and a second display portion, and a light transmittance of the first display portion is greater than a light transmittance of the second display portion.

18. The display terminal according to claim 10, wherein the first sub-pixel is a green sub-pixel, the second sub-pixel is a red sub-pixel, and the third sub-pixel is a blue sub-pixel.
